(19) United States
(12) Patent Application Publication
(10) Pub. No.: US 2019/0067208 A1
(43) Pub. Date: Feb. 28, 2019

(54) CIRCUIT BOARD AND CHIP PACKAGE

(71) Applicant: MStar Semiconductor, Inc., Hsinchu Hsien (TW)

(72) Inventor: You-Wei Lin, Hsinchu Hsien (TW)

(21) Appl. No.: 15/850,460

(22) Filed: Dec. 21, 2017

(30) Foreign Application Priority Data
Aug. 28, 2017 (TW) 106129157

(51) Int. Cl. H01L 23/552; H01L 23/498; H01L 23/31

(52) U.S. Cl. CPC H01L 23/552; H01L 23/49816; H01L 24/48; H01L 23/49838; H01L 23/49822; H01L 23/3128

(57) ABSTRACT

A chip package includes a circuit board, an encapsulation, a plurality of conductive structures and an electromagnetic interference (EMI) protection layer. The circuit board includes a plurality of ground conductive pads disposed on a lower surface thereof. The encapsulation is disposed on an upper surface of the circuit board. The conductive structures are disposed in the encapsulation, and are electrically connected to the ground conductive pads. End points of the conductive structures are revealed from a sidewall of the encapsulation. The EMI protection layer is disposed on the encapsulation, and is electrically connected to the ground conductive pads through the end points of the conductive structures.

This application claims the benefit of Taiwan application Serial No. 106129157, filed on Aug. 28, 2017, the subject matter of which is incorporated herein by reference.

### BACKGROUND OF THE INVENTION

### Field of the Invention

The invention relates to a circuit board and a chip package, and more particularly, to a circuit board and a chip package having, revealed from a side thereof, ground conductive wires for electrically connecting to an electromagnetic interference (EMI) protection layer.

### Description of the Related Art

A semiconductor package is a technology for sealing one or more dies into an integral to provide the dies with protection against certain impacts and friction. With the evolving technologies, the size of dies is ever-decreasing, the traces and routings therein are becoming denser, and the electromagnetic interference (EMI) of a chip package also gets more severe. Thus, an EMI protection layer is included in a chip package. The EMI protection layer is electrically connected to a ground conductive wire to provide EMI protection. However, repeated plugging to and unplugging from a test a slot during tests wears the EMI protection layer due to friction between the EMI protection layer and the ground conductive wire to further form an open circuit, thus causing an antenna effect at the EMI protection layer.

### SUMMARY OF THE INVENTION

It is an object of the present invention to provide a chip package and a circuit board. Through conductive structures revealed at a sidewall of an encapsulation or end points of multiple conductive wires revealed at a sidewall of the circuit board, the probability of an open circuit between an electromagnetic interference (EMI) protection layer and ground conductive wires that is caused by tests can be reduced.

A chip package according to an embodiment of the present invention includes a circuit board, an encapsulation, a plurality of conductive structures and an EMI protection layer. The circuit board has an upper surface and a lower surface that are opposite, and includes a plurality of ground conductive pads disposed on the lower surface. The encapsulation is disposed on the upper surface of the circuit board. The conductive structures are disposed in the encapsulation, and are electrically connected to the ground conductive pads, respectively. End points of the conductive structures are revealed from a sidewall of the encapsulation. The EMI protection layer is disposed on the encapsulation, and is electrically connected to the ground conductive pads through the end points of the conductive structures.

A circuit board according to another embodiment of the present invention includes an insulation layer and a plurality of ground traces and routings. The ground traces and routings are disposed in the insulation layer, and each includes a plurality of ground conductive wires. End points of the ground conductive wires are revealed from a sidewall of the circuit board, and overlap in a top view direction of the circuit board.

The above and other aspects of the invention will become better understood with regard to the following detailed description of the non-limiting embodiments. The following description is made with reference to the accompanying drawings.

### BRIEF DESCRIPTION OF THE DRAWINGS

FIG. 1 is a side view of a chip package according to a first embodiment of the present invention;

FIG. 2 is a section view of the chip package along a section line A-A′ in FIG. 1 according to the first embodiment of the present invention;

FIG. 3 is a side view of a chip package according to a second embodiment of the present invention;

FIG. 4 is a section view of the chip package along a section line A-A′ in FIG. 3 according to the second embodiment of the present invention;

FIG. 5 is a section view of a chip package according to a third embodiment of the present invention;

FIG. 6 is a side view of a circuit board viewing from an arrow in FIG. 5 according to the third embodiment of the present invention;

FIG. 7 is a section view of a chip package according to a fourth embodiment of the present invention; and

FIG. 8 is a section view of a chip package according to a fifth embodiment of the present invention.

### DETAILED DESCRIPTION OF THE INVENTION

For one skilled in the art to better understand the present invention, embodiments are given in detail with the accompanying drawings to explain the concept and expected effects of the present invention. To keep the description simple and easy to understand, the drawings are not depicted according to actual sizes and ratios of finishes products. The sizes and ratios of the components in the drawings are illustrative, and are not to be construed as limitations to the present invention.

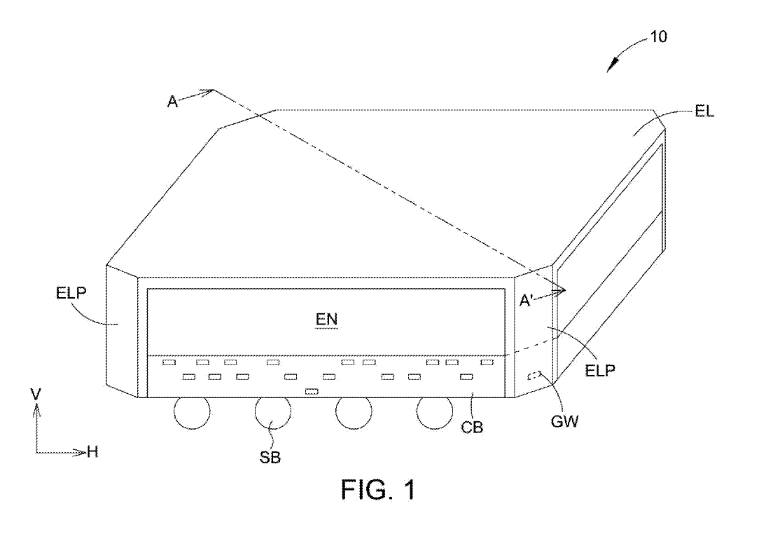

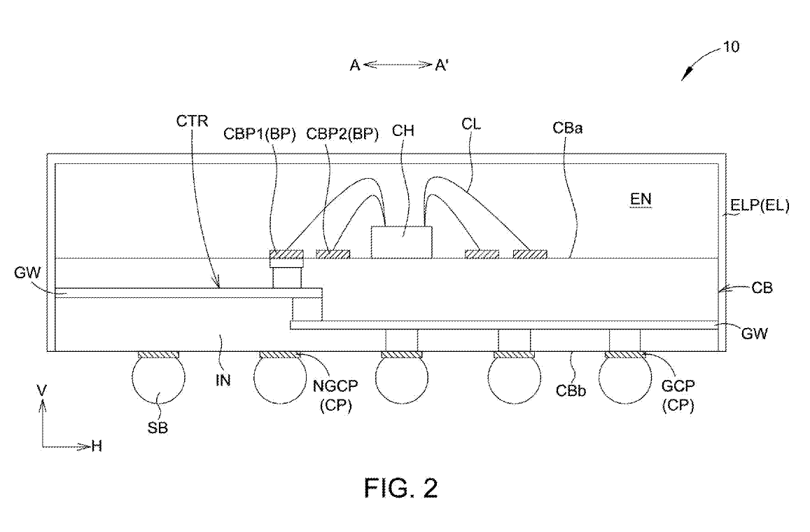

FIG. 1 shows a section view of a chip package according to a first embodiment of the present invention. FIG. 2 shows a section view of the chip package along a section line A-A′ in FIG. 1 according to the first embodiment of the present invention. As shown in FIG. 1 and FIG. 2, the chip package 10 includes a circuit board CB, an electronic device CH, an encapsulation EN and an electromagnetic interference (EMI) protection layer EL. The circuit board CB has an upper surface CBa and a lower surface CBb that are opposite, and includes an insulation layer IN, a plurality of pads BP, a plurality of conductive pads CP, and a plurality of chip traces and routings CTR. The insulation layer IN is disposed between the upper surface CBa and the lower surface CBb. The pads BP are disposed on the upper surface CBa. The conductive pads CP are disposed on the lower surface CBb. The chip traces and routings CTR are disposed in the insulation layer IN. The electronic device CH (e.g., a chip) is disposed on the upper surface CBa of the circuit board CB, and may be electrically connected to the pads BP through conductive wires CL, for example, so as to connect to the corresponding conductive pads CP through the pads BP and the chip traces and routings CTR. The pads BP may include chip pads CBP1 and CBP2. The chip pad CBP1 is for electrically connecting to the ground terminal of the electronic device CH, and the chip pad CBP2 is for electrically connecting to a non-ground signal terminal of the electronic device CH. The conductive pads CP may include a ground conductive pad GCP and a non-ground conductive pad NGCP. The ground conductive pad GCP is for electrically connecting to an external ground terminal, and the non-ground conductive pad NGCP is for electrically connecting to an external non-ground terminal. One person skilled in the art should know that the chip traces and routings CTR can have different structures according to design requirements. For example, the chip traces and routings CTR may be formed by multiple conductive wire layers WL and multiple conductive vias. The insulation layer IN may include a plurality of insulation layers. Each conductive wire layer WL may be disposed between any two adjacent insulation layers, so as to separate adjacent conductive wire layers WL by the insulation layer in between. Further, each of the conductive vias may penetrate through one or multiple insulation layers. Thus, in the same chip wire and routing CTR, the conductive wires may achieve electrical connection in the horizontal direction H, and the vias may achieve electrical connection in the vertical direction V.

The encapsulation EN is disposed on the upper surface CBa of the circuit board CB to tightly seal the electronic device CH. The EMI protection layer EL is disposed on and covers the encapsulation EN, and may include at least two connecting portions ELP separated from each other and extending from an upper surface of the encapsulation EN to the sidewall of the circuit board CB. It should be noted that, one of the chip traces and routings CTR can be used to electrically connect the chip pad CPB1 to a ground trace and routing of the ground conductive pad GCP. The ground trace and routing includes a plurality of ground conductive wires GW formed by different conductive layers WL, and end points of at least two of the ground conductive wires GW may be respectively revealed from different parts of the sidewall of the circuit board CB to respectively come into contact with different connecting portions ELP. As such, each of the connecting portions ELP extending to the sidewall of the circuit board CB can be electrically connected to the end point of the corresponding ground conductive wire GW to further electrically connect to the ground conductive pad GCP, thereby allowing the EMI protection layer EL to provide an EMI protection function.

However, because the chip package 10 is repeatedly plugged to and unplugged from a test slot during tests and the sidewall of the circuit board CB comes into complete contact with the test slot during the tests, the connecting portions ELP of the EMI protection layer EL located at the sidewall of the circuit board CP are susceptible to disengagement due to friction against the test slot, leading an open circuit between the EMI protection layer EL and the ground conductive wires GW and generating an antenna effect of the EMI protection layer EL.

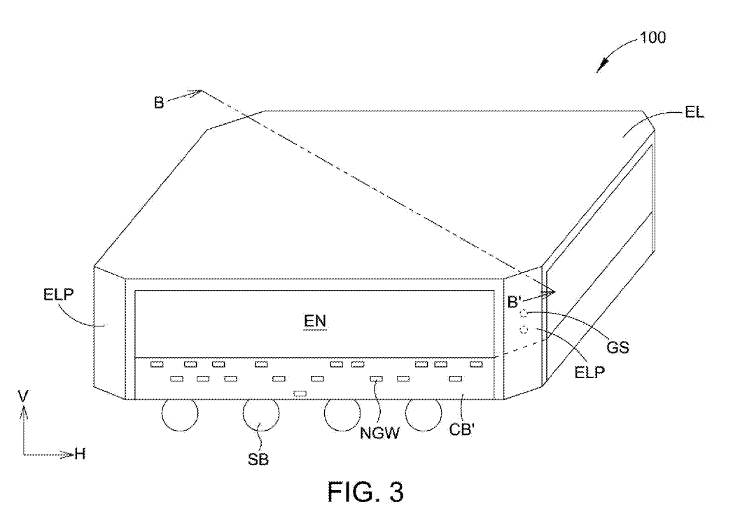

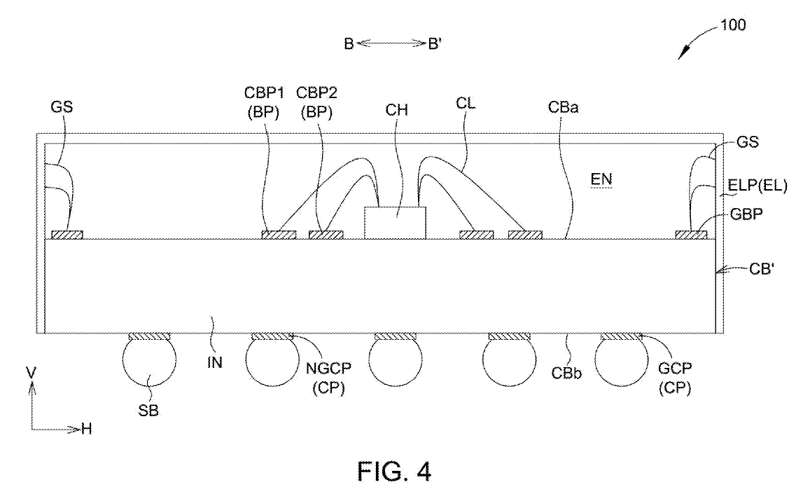

FIG. 3 shows a side view of a chip package according to a second embodiment of the present invention. FIG. 4 shows a section view of the chip package along a section line A-A′ in FIG. 3 according to the second embodiment of the present invention. Differences between the chip package 100 in FIG. 3 and FIG. 4 and the chip package 10 in FIG. 1 and FIG. 2 are that, the chip package 100 further includes a plurality of conductive structures GS, which are disposed in the encapsulation EN and are electrically connected to the ground conductive pad GCP. The conductive structures GS may be, for example but not limited to, metal wires. In this embodiment, the pads BP of a circuit board CB′ may further include a plurality of ground pads GBP, which are disposed near the sidewall of the circuit board CB′ and are electrically connected to the ground conductive pad GCP. Further, each conductive structure GS may be connected to the ground pads GBP and extend from the upper surface CBa of the circuit board CB′ to the sidewall of the encapsulation EN so as to reveal the end point of each conductive structure GS from the sidewall of the encapsulation EN. Thus, because the connecting portions ELP of the EMI protection layer EL are extended to the sidewall of the encapsulation, the EMI protection layer EL can electrically connect to the ground pads GBP through the contact with the conductive structures GS, so as to further electrically connect to the ground conductive pad GCP and achieve the effect of EMI protection. To prevent the conductive structures GS extending to the sidewall of the encapsulation EN and the ground pads GBP from affecting the configuration of the electronic device CH and the conductive wires CL, the conductive structures GS and the ground pads GBP may be located, e.g., between the chip pads CBP1,CBP2 and the circuit board CB′.

In one embodiment, the routings and traces of the circuit board CB′ in the insulation layer IN of the chip package 100 may be similar to those of the circuit board CB in the insulation layer IN in the chip package 10 in FIG. 2, and the ground pads GBP of the circuit board CB′ may be electrically connected to the ground conductive wire GW through the vias as shown in FIG. 2.

Thus, since the ends of the conductive structures GS are revealed from the sidewall of the encapsulation EN, electrical connection positions of the EMI protection layer EL and the conductive structures GS can be away from the test slot, thereby maintaining the electrical connection between the EMI protection layer EL and the ground conductive pad GCP, preventing an antenna effect.

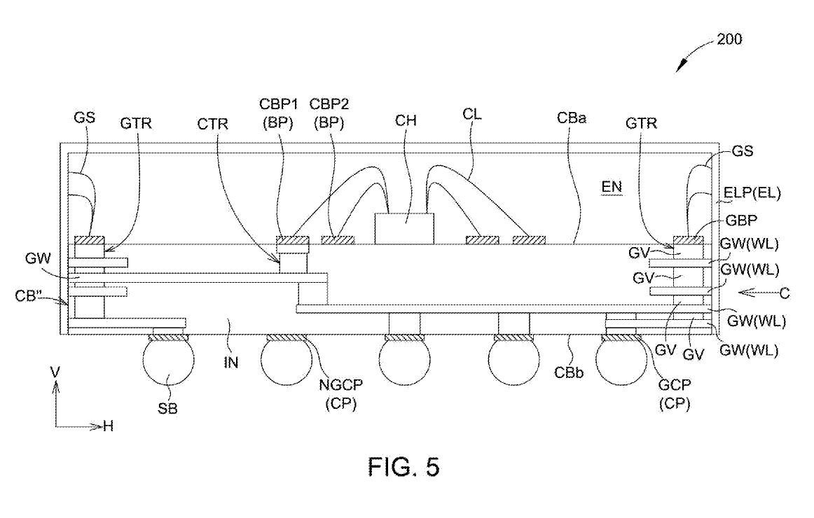

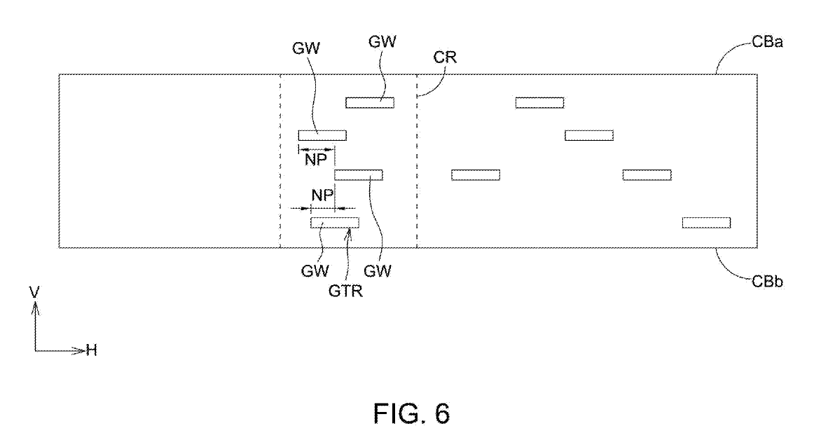

The circuit board of the present invention is not limited to the design of the above embodiments. FIG. 5 shows a section view of a chip package 200 according to a third embodiment of the present invention. FIG. 6 shows a side view of the chip package 200 viewing from an arrow C in FIG. 5 of the present invention. Difference between the chip package 200 and the chip package 100 in FIG. 3 and FIG. 4 are that, the circuit board CB″ of the chip package 200 may further include a plurality of ground traces and routings GTR disposed in the insulation layer IN, and the ground pads GBP may electrically connect to the ground conductive pads GCP through the ground traces and routings GTR. More specifically, each ground trace and routing GTR may include a plurality of ground conductive wires GW, which are respectively formed by different conductive layers WL and are electrically connected to one another through ground vias GV, so as to electrically connect the ground pads GBP located at the upper surface CBa of the circuit board CB″ to the ground conductive pads GCP at the lower surface CBb of the circuit board CB″. In this embodiment, the ground conductive wires GW of different ground traces and routings GTR may be electrically connected to one another so as to have the ground traces and routings GTR to be electrically connected to one another, for example. In another embodiment, the ground conductive wires GW of different ground traces and routings GTR may also be separated from one another so as to electrically insulate different ground traces and routings GTR.

In this embodiment, at least two of the ground conductive wires GW of the ground traces and routings GTR may extend to a sidewall of the circuit board CB″, so that end points of the at least two of the ground conductive wires GW of the ground traces and routings GTR can be revealed from the sidewall of the circuit board CB″ to facilitate the electrical connection to the connecting portions ELP of the EMI protection layer EL; that is, the circuit board CB″ may be a plating line (PL) circuit board. For example, the sidewall of the circuit board CB″ may include a plurality of connecting regions CR, which respectively extend from the upper surface CBa to the lower surface CBb and are for disposing the connecting portions ELP of the EMI protection layer EL. Further, the ground conductive wires GW corresponding to the same ground trace and routing GTR may be revealed from the same connecting region CR so as to be connected to the same connection portion ELP. Thus, the number of the connecting portions ELP may be equal to the number of the ground traces and routings GTR. For example, the number of the connecting portions ELP may be an even number, e.g., two, four or more.

It should be noted that, because the end points of at least two of the ground conductive wires GW of the ground traces and routings GTR can be revealed from the sidewall of the circuit board CB″ to increase the number of the connecting points of the connection portions ELP to the corresponding ground traces and routings GTR, the probability of disconnection caused by friction on the electrical connections between the connecting portions ELP and the corresponding ground traces and routings GTR can be reduced, so as to prevent an antenna effect of the chip package 200. To facilitate the ground conductive wires GW of the same ground trace and routing GTR to extend to the sidewall of the circuit board CB″, the ground traces and routings GTR corresponding to the ground pads GBP are preferably located between the chip traces and routings CTR and the sidewall of the circuit board CB″.

It should be noted that, the two adjacent revealed end points, of the ground conductive wires GW corresponding to the same ground trace and routing GTR, are overlapping in a top view direction of the circuit board CB″, and such characteristic is against a conventional design principle of spaced end points; that is, a pitch NP, in the horizontal direction H, between the two adjacent revealed end points of the ground conductive wires GW is smaller than 80 μm. More specifically, because the chip package 200 including the circuit board CB″ is repeatedly plugged to and unplugged from a test slot during tests, end points of the circuit board CB″ are likely pressed by the test slot in a way that metal lines are extended towards the upper surface CBa. In a conventional circuit board, a manufacturing alignment error between upper and lower adjacent conductive layers WL is about 50 μm and a width of an end point of a conductive wire is about 20 μm, for example, and the end points revealed from the sidewall of the circuit board are not necessary electrically connected to the same chip trace and routing. Thus, to prevent the extension of metal at an end point from causing a short circuit, when designing the configuration for revealing end points, the design principle is setting a pitch, in the horizontal direction, of two adjacent end points in two upper and lower adjacent conductive layers WL to be greater than or equal to about 80 μm. However, in this embodiment, the ground conductive wires GW of the same ground trace and routing GTR are electrically connected, and therefore no issue is caused even if a short circuit occurs between the two.

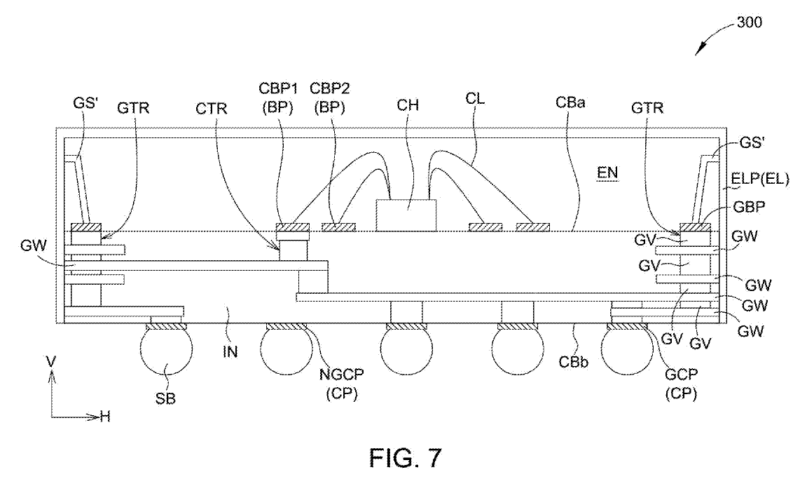

FIG. 7 shows a section view of a chip package 300 according to an embodiment of the present invention. Compared to the chip package 200 in FIG. 5, conductive structures GS′ of the chip package 300 may be metal plates.

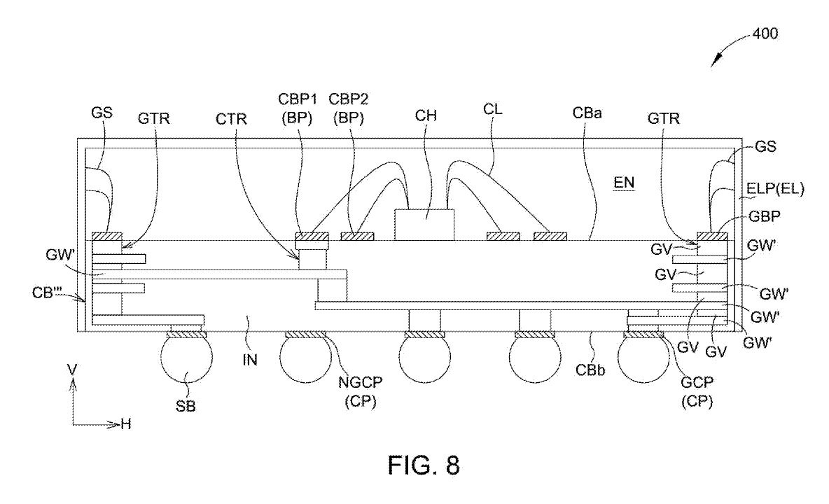

FIG. 8 shows a section view of a chip package 400 according to an embodiment of the present invention. Compared to the chip package 200 in FIG. 5, ground conductive wires GW′ of a circuit board CB′″ of the chip package 400 are not required to extend to the sidewall of the circuit board CB′″, such that the end points of the ground conductive wires GW′ are not revealed at the sidewall of the circuit board CB′″. That is to say, the circuit board CB′″ may be a non-plating line (NPL) circuit board. In this embodiment, the EMI protection layer EL may still be electrically connected to the ground conductive pads GCP through the conductive structures GS.

While the invention has been described by way of example and in terms of the embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A chip package, comprising:
a circuit board, having an upper surface and a lower surface opposite to each other, comprising a plurality of ground conductive pads disposed on the lower surface;
an encapsulation, disposed on the upper surface of the circuit board;
a plurality of conductive structures, disposed in the encapsulation, respectively electrically connected to the ground conductive pads, wherein one end of each of the conductive structures is revealed from a sidewall of the encapsulation; and
an electromagnetic interference (EMI) protection layer, disposed on the encapsulation, electrically connected to the ground conductive pads through the end points of the conductive structures,
wherein the circuit board further comprises a plurality of ground pads disposed on the upper surface, and the conductive structures are electrically connected to the ground conductive pads through the ground pads,
wherein the circuit board further comprises an insulation layer and a plurality of ground traces and routings disposed in the insulation layer, and the ground pads are electrically connected to the ground conductive pads through the ground traces and routings, and
wherein each of the ground traces and routings comprises a plurality of ground conductive wires electrically connected to one another, end points of at least two of the ground conductive wires are revealed from the sidewall of the circuit board, and the EMI protection layer is in contact with the revealed end points of the at least two of the ground conductive wires.

2-4. (canceled)

5. The chip package according to claim 1, wherein the revealed end points of the at least two of the conductive wires overlap in a top view direction of the circuit board.

6. The chip package according to claim 1, wherein a pitch, in a horizontal direction, of the revealed end points of the at least two of the conductive wires is smaller than 80 μm.

7. The chip package according to claim 1, wherein each of the conductive structures comprises a metal line or a metal plate.

8. A circuit board, comprising:
an insulation layer; and
a plurality of ground traces and routings, disposed in the insulation layer, each of the ground traces and routings comprising a plurality of ground conductive wires, wherein one end point of each ground conductive wire is revealed from a sidewall of the circuit board, and the revealed end points of the ground conductive wires overlap in a top view direction of the circuit board.

9. The circuit board according to claim 8, further comprising a plurality of ground pads disposed on an upper surface of the circuit board and a plurality of ground conductive pads disposed on a lower surface of the circuit board, and the ground pads are electrically connected to the ground conductive pads through the ground traces and routings.

10. The circuit board according to claim 8, wherein a pitch, in a horizontal direction, between two adjacent of the end points is smaller than 80 μm.
